(19) United States
(12) Patent Application Publication
(10) Pub. No.: US 2022/0039293 A1
(43) Pub. Date: Feb. 3, 2022

(54) Thermally Conductive Sheet Precursor, Thermally Conductive Sheet Obtained From Precursor, and Method For Manufacturing Same

(71) Applicant: 3M INNOVATIVE PROPERTIES COMPANY, St. Paul, MN (US)

(72) Inventor: Ricardo Mizoguchi Gorgoll, Sagamihara-shi, Kanagawa (JP)

(21) Appl. No.: 17/279,663

(22) PCT Filed: Sep. 23, 2019
(86) PCT No.: PCT/IB2019/058051

§ 371 Date: Mar. 25, 2021

(30) Foreign Application Priority Data
Sep. 26, 2018 (JP) 2018-180507

(51) Int. Cl. H05K 7/20; H01L 23/373; H01L 23/367; H01L 21/48

(52) U.S. Cl. CPC H05K 7/20481; H01L 23/3736; H05K 7/20854; H01L 21/4871; H01L 23/367

(57) ABSTRACT

A thermally conductive sheet precursor according to an embodiment of the present disclosure includes agglomerates in which anisotropic thermally conductive primary particles are agglomerated, an isotropic thermally conductive material different from the agglomerates and having an average particle diameter of about 20 μm or greater, and a binder resin. When a first pressure in a range from about 0.75 to about 12 MPa is applied to the thermally conductive sheet precursor, at least some the agglomerates disintegrate.

### TECHNICAL FIELD

The present disclosure relates to a thermally conductive sheet precursor excellent in thermal conductivity, a thermally conductive sheet obtained from the precursor, and a method for manufacturing the same.

### BACKGROUND ART

Heat generating components such as semiconductor elements may suffer from problems such as reduced performance and breakage due to heat generation during use. In order to eliminate such problems, sheets with thermal conductivity are used in the assembly of power modules of electric vehicles (EV) in which a semiconductor heat spreader is attached to a heat sink, for example.

Patent Literature 1 (JP 5184543 B) discloses a thermally conductive sheet obtained by dispersing an inorganic filler in a thermosetting resin, wherein the inorganic filler contains spherical secondary agglomeration particles formed by isotropically agglomerating and sintering scaly boron nitride primary particles having an average long diameter of 15 μm or less and scaly boron nitrides and/or spherical inorganic powder having an average long diameter from 3 μm to 50 μm, and the inorganic filler contains more than 20 vol % of the secondary agglomeration particles having a particle diameter of 50 μm or greater, and scaly boron nitrides having an average long diameter from 3 μm to 50 μm are isotropically oriented in the thermally conductive sheet.

Patent Literature 2 (WO 2011/111684A1) discloses a thermally conductive laminate including an insulating layer having at least one filler-containing polyimide resin layer that contains a thermally conductive filler in a polyimide resin, and a metal layer layered on one surface or both surfaces of the insulating layer, in which a content ratio of the thermally conductive filler in the filler-containing polyimide resin layer is in a range from 35 to 80 vol %, the thermally conductive filler has the maximum particle diameter of less than 15 μm, the thermally conductive filler contains a plate-like filler and a spherical filler, the plate-like filler has an average long diameter DL in a range from 0.1 to 2.4 μm, and the insulating layer has a thermal conductivity rate λz of 0.8 W/mK or higher in a thickness direction of the insulating layer.

### CITATION LIST

Patent Literature 1: JP 5184543 B
Patent Literature 2: WO 2011/111684

### SUMMARY OF INVENTION

In recent years, there has been a demand for new thermally conductive sheets with improved thermal conductivity, for example, as power modules are miniaturized, power is increased, performance is heightened and the like in electric vehicles.

Accordingly, the present disclosure provides a precursor of a thermally conductive sheet excellent in thermal conductivity, a thermally conductive sheet obtained from the precursor, and a method for manufacturing the same.

### Solution to Problem

According to one embodiment of the present disclosure, provided is a thermally conductive sheet precursor including agglomerates in which anisotropic thermally conductive primary particles are agglomerated, an isotropic thermally conductive material different from the agglomerates and having an average particle diameter of about 20 μm or greater, and a binder resin, in which when a first pressure in a range from about 0.75 to about 12 MPa is applied to the thermally conductive sheet precursor, at least some the agglomerates disintegrate.

According to another embodiment of the present disclosure, a thermally conductive sheet formed from the thermally conductive sheet precursor described above is provided.

According to another embodiment of the present disclosure, provided is a method for manufacturing a thermally conductive sheet, including preparing a mixture including agglomerates in which anisotropic thermally conductive primary particles are agglomerated, an isotropic thermally conductive material different from the agglomerates and having an average particle diameter of about 20 μm or greater, and a binder resin, forming a thermally conductive sheet precursor by using the mixture, and applying pressure of at least about 0.75 MPa to the thermally conductive sheet precursor to form a thermally conductive sheet.

### Advantageous Effects of Invention

The thermally conductive sheet precursor, the thermally conductive sheet obtained from the precursor, and the manufacturing method of the same according to the present disclosure can improve thermal conductivity, particularly isotropic thermal conductivity, of the resulting thermally conductive sheet.

The above descriptions should not be construed as that all embodiments of the present disclosure and all advantages of the present disclosure are disclosed.

### BRIEF DESCRIPTION OF DRAWINGS

FIG. 1(a) is a SEM photograph of a thermally conductive sheet precursor including agglomerates to which a pressure of 0.1 MPa is applied according to the present disclosure, and FIG. 1(b) is a SEM photograph of a thermally conductive sheet precursor including agglomerates to which a pressure of 3 MPa is applied according to the present disclosure.

FIG. 2(a) is a cross-sectional SEM photograph of a thermally conductive sheet according to an embodiment of the present disclosure, and FIG. 2(b) is an enlarged SEM photograph of a portion of the thermally conductive sheet where an isotropic thermally conductive material (AlN) and agglomerates are disintegrated according to an embodiment of the present disclosure. Both thermally conductive sheets include agglomerates (A150) and an isotropic thermally conductive material (F50) at a ratio of 1:1.

FIG. 3(a) is an optical microscopic photograph of a thermally conductive sheet precursor including agglomerates, after being sintered, to which a pressure is not applied according to the present disclosure, and FIG. 3(b) is an optical microscopic photograph of a thermally conductive sheet precursor including agglomerates, after being sintered, to which a pressure at which the agglomerates are disintegrated is applied according to the present disclosure.

FIG. 4 is a graph illustrating a relationship between a compounding ratio of an isotropic thermally conductive material and a thermal conductivity rate in thermally conductive sheets containing various thermally conductive materials.

FIG. 5(a) is an enlarged SEM photograph of a portion of a thermally conductive sheet (including agglomerates (A150) and an isotropic thermally conductive material (F50) at a ratio of 1:1) where an isotropic thermally conductive material (AlN) and agglomerates are disintegrated according to an embodiment of the present disclosure, and FIG. 5(b) is an enlarged SEM photograph of an isotropic thermally conductive material and anisotropic thermally conductive primary particles in a thermally conductive sheet, the thermally conductive sheet being prepared using a mixture containing an isotropic thermally conductive material (AlN:F50) and an anisotropic thermally conductive primary particles (BN:P015) at a ratio of 1:1.

### DESCRIPTION OF EMBODIMENTS

A thermally conductive sheet precursor according to a first embodiment of the present disclosure includes agglomerates in which anisotropic thermally conductive primary particles are agglomerated, an isotropic thermally conductive material different from the agglomerates and having an average particle diameter of about 20 μm or greater, and a binder resin. When a first pressure in a range from about 0.75 to about 12 MPa is applied to the thermally conductive sheet precursor, at least some the agglomerates disintegrate.

In a case that a sheet is formed from a resin material in which primary particles of anisotropic thermally conductive particles such as scaly boron nitride are simply blended, such particles are likely to align in one direction, and therefore, the resulting sheet is less likely to exhibit isotropic thermal conductivity. However, the thermally conductive sheet precursor according to the present disclosure employs agglomerates that can disintegrate at a first pressure, and therefore, the anisotropic thermally conductive primary particles constituting the agglomerates are likely to align in a random direction after disintegration, and therefore, the resulting thermally conductive sheet is thought to be likely to exhibit the isotropic thermally conductivity (sometimes referred to simply as “thermally conductivity”).

The thermally conductive sheet according to the present disclosure also includes an isotropic thermally conductive material having a relatively large average particle diameter of about 20 μm or greater. As a result, as compared to a case that the same amount of isotropic thermally conductive material a size of which is smaller than the above size is used, a ratio of an interface between the isotropic thermally conductive material and the binder resin is reduced and an isotropic thermally conductive path is easily obtained, and therefore, the thermally conductive sheet is thought to be more likely to exhibit the isotropic thermal conductivity.

The isotropic thermally conductive material included in the thermally conductive sheet precursor according to the first embodiment may be those not disintegrate when the first pressure is applied to the thermally conductive sheet precursor. By using such a material, the thermally conductive sheet obtained by the method according to the present disclosure is more likely to exhibit the isotropic thermal conductivity.

The agglomerates included in the thermally conductive sheet precursor according to the first embodiment may have a void space ratio greater than about 50%. Such agglomerates are more likely to be disintegrated and randomized at a given pressure, and therefore, likely to exhibit the isotropic thermal conductivity to the thermally conductive sheet.

In the thermally conductive sheet precursor according to the first embodiment, a filler component can be included in the precursor at about 45 to about 80 vol %, and a ratio of the agglomerates in the filler component can be about 20 to about 95% and a ratio of the isotropic thermally conductive material in the filler component can be about 5 to about 80%. The thermally conductive sheet precursor including the agglomerates and the isotropic thermally conductive material at such a compounding ratio can further improve the isotropic thermal conductivity of the finally resulting thermally conductive sheet.

An average particle diameter of the agglomerates included in the thermally conductive sheet precursor according to the first embodiment may be about 20 μm or greater. The agglomerates having such a size, in which the anisotropic thermally conductive primary particles constituting the agglomerates are likely to be randomized after disintegration, is likely to exhibit the isotropic thermal conductivity to the thermally conductive sheet.

The agglomerates included in the thermally conductive sheet precursor according to the first embodiment can include boron nitride primary particles. Boron nitride is excellent in thermal conductivity and insulating properties, and thus employing such particles can improve both performances for the thermally conductive sheet.

The thermally conductive sheet precursor according to the first embodiment may have a thickness greater than a maximum value of a short axis length (a length of the smallest side) of the agglomerates. Such a thickness can reduce defects such as the agglomerates dropping-out.

The isotropic thermally conductive material included in the thermally conductive sheet precursor according to the first embodiment may be at least one selected from aluminum nitride, aluminum oxide, silicon carbide, and boron nitride. Using such a material can further improve the isotropic thermal conductivity of the final resulting thermally conductive sheet.

The thermally conductive sheet precursor according to the first embodiment may further include a filler. The filler can fill, after applying the first pressure, at least partially a low density portion such as void spaces located between the agglomerates before applying the first pressure to reduce the intrusion of electrons, and therefore, can improve the insulating properties for the thermally conductive sheet. In a case that a filler excellent in the thermal conductivity is used, the filler can also contribute to improvement in the thermal conductivity.

A thermally conductive sheet of a second embodiment of the present disclosure is formed from the thermally conductive sheet precursor of the first embodiment.

The thermally conductive sheet according to the second embodiment can have at least one or more potions where a plurality of anisotropic thermally conductive primary particles disintegrating from the agglomerates locally congregate in a circular region of about 20 to about 150 μm diameter in a cross section in the thickness direction. The thermally conductive sheet obtained by applying the first pressure to the thermally conductive sheet precursor according to the first embodiment of the present disclosure includes the locally congregated portion, differently from a thermally conductive sheet obtained from a resin material in which the agglomerates and an isotropic thermally conductive material are simply mixed, and therefore, can improve the isotropically thermal conductivity.

A method for manufacturing a thermally conductive sheet according to a third embodiment of the present disclosure includes preparing a mixture including agglomerates in which anisotropic thermally conductive primary particles are agglomerated, an isotropic thermally conductive material different from the agglomerates and having an average particle diameter of about 20 μm or greater, and a binder resin, forming a thermally conductive sheet precursor by using the mixture, and applying pressure of at least about 0.75 MPa to the thermally conductive sheet precursor to form a thermally conductive sheet. The thermally conductive sheet obtained by the method can improve isotropic thermal conductivity.

Hereinafter, a more detailed description is given for the purpose of illustrating representative embodiments of the present disclosure, but the present disclosure is not limited to these embodiments.

In the present disclosure, a “sheet” includes articles referred to as a “film”.

In the present disclosure, “(meth)acrylic” means acrylic or methacrylic.

In the present disclosure, “anisotropic thermal conductivity” or “anisotropy thermal conductivity” means that the thermal conductivity varies with a direction. For example, it can be intended that as compared to a thermal conductivity rate in a direction of the highest thermal conductivity rate, a thermal conductivity rate in another direction is lower by about 50% or more, about 60% or more, or about 70% or more. Here, the above-described another direction may be intended to differ from the direction of the highest thermal conductivity rate in a range from about 10 degrees or more, about 20 degrees or more, or about 30 degrees or more, and about 90 degrees or less. Examples of a material exhibiting such anisotropic thermal conductivity include scaly boron nitride. It is known that such boron nitride exhibits an anisotropic thermal conductivity in which a thermal conductivity rate in a long diameter direction (crystal direction) is high and a thermal conductivity rate in a short diameter direction (a thickness direction, or a direction at 90 degrees with respect to the long diameter direction) is low.

In the present disclosure, the “isotropic thermal conductivity” or “isotropy thermal conductivity” means being substantially isotropic, specifically being less anisotropic in thermal conductivity than an anisotropic thermally conductive material. For example, substantially spherical alumina particles are known to exhibit isotropic thermal conductivity in which the thermal conductivity is substantially equal in any direction. In the present disclosure, a term “substantially” refers to including variations caused by manufacturing errors or the like, and may be intended to mean that about 5 to about 30%, preferably about 5 to about 20% variation is acceptable.

In the present disclosure, a term “disintegration” means that a secondary structure congregating primary structures collapses and substantially returns to a form of the primary structures. For example, “at least some of agglomerates in which anisotropic thermally conductive primary particles agglomerate disintegrates” means that at least some of the primary particles constituting the agglomerates collapse by a pressure and substantially return to the form of the primary particles prior to agglomeration. Here, a phrase “substantially return” may be intended, for example, to mean that a shape or size of the primary structure after disintegration maintains at about 70% or more, about 75% or more, or about 80% or more relative to the shape or size of the primary structure prior to the disintegration.

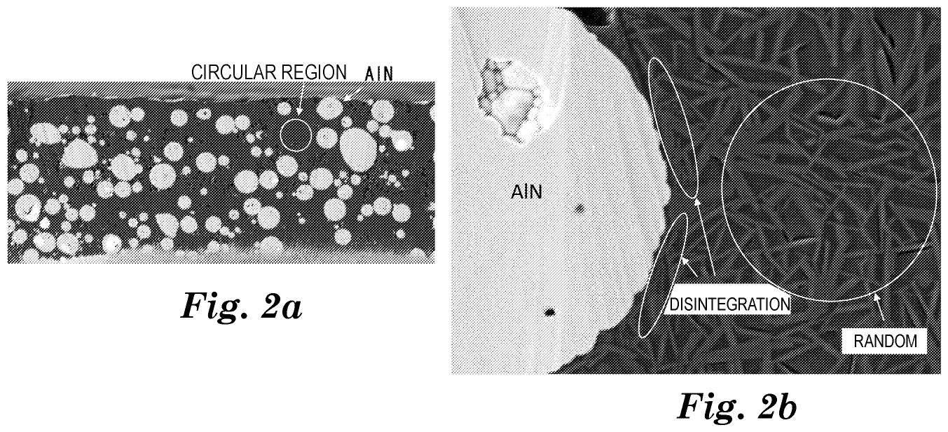

In the present disclosure, a term “break” means that the primary structure itself breaks. For example, in FIG. 2(b), particles can be seen around aluminum nitride (AlN) that are significantly smaller than the sizes of boron nitride primary particles. These small particles can be said to be boron nitride primary particles broken by aluminum nitride.

In the present disclosure, a term “random” means a state that is directionally disordered. For example, in a sheet containing scaly boron nitride, a state in which boron nitride is arranged substantially parallel to a main surface of the sheet is not “random”, and the state illustrated in FIG. 2(b) is “random”.

Thermally Conductive Sheet Precursor

### Agglomerate

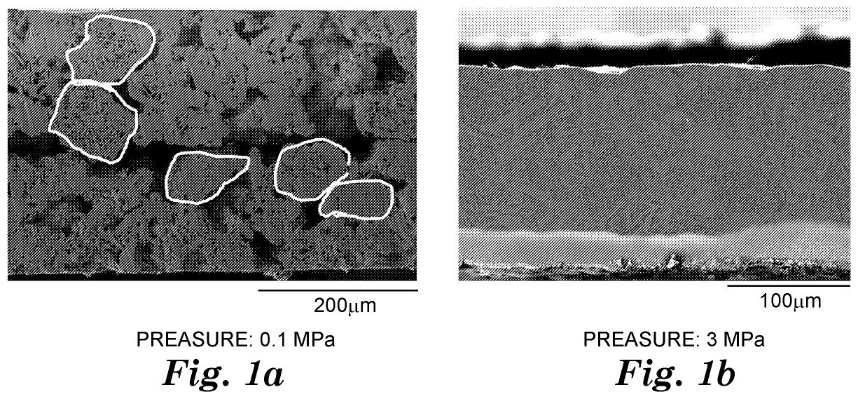

Agglomerates included in the thermally conductive sheet precursor according to the present disclosure are secondary agglomerated particles in which the anisotropic thermally conductive primary particles agglomerate, like portions surrounded by white lines in FIG. 1(a). Any agglomerates can be used as long as at least some of the agglomerates disintegrate when a predetermined pressure is applied to the thermally conductive sheet precursor. It is preferable that the agglomerates include the anisotropic thermally conductive primary particles randomly agglomerating and has a thermal conductivity rate more isotropic than the primary particles. Here, the agglomerates do not need to disintegrate in the precursor at a predetermined pressure, for example, all pressures within a range from about 0.75 to about 12 MPa, and at least some of the agglomerates may disintegrate when any pressure within such range (first pressure) is applied.

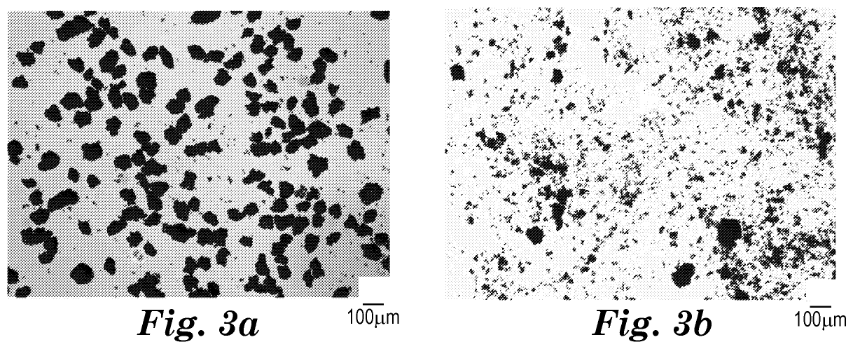

From the perspective of the thermal conductivity, the agglomerates preferably have a disintegration rate of about 2% or higher, about 3% or higher, or about 4% or higher, per 1 mm² after pressure application, as illustrated in FIG. 3. An upper limit value of the disintegration rate is not particularly limited, but can be defined as, for example, about 100% or lower, about 95% or lower, or about 90% or lower per 1 mm². Here, the disintegration rate refers to a rate of change of an area mean diameter obtained from the particle distribution analysis (ImageJ software (version 1.50i)) of an optical microscopic image of the agglomerates recovered from the sheet.

Void Space Ratio of Agglomerate

The agglomerates may have a void space ratio greater than about 50%, and may have a void space ratio of about 60% or higher, or about 70% or higher, in view of disintegrability after pressure application. Such void space ratio can be controlled by adjusting a sintering temperature of the agglomerates, for example. In a case that the sintering temperature is high, the agglomerates are shrank and densified, and therefore, a strength of the agglomerates increase, but the void space ratio decreases. On the other hand, in a case that the sintering temperature is low, shrinkage of the agglomerates is reduced, and therefore, the void space ratio can be increased without increasing the strength of the agglomerates. Here, in the case of high temperature sintering, the agglomerates tend to exhibit a spherical form, while in the case of low temperature sintering, the agglomerates tend to exhibit an incomplete spherical shape, that is, a non-spherical form. The void space ratio of the agglomerates can be calculated, for example, from a bulk density of the agglomerates or can be determined by measuring a pore volume by a mercury intrusion method.

Size of Agglomerates

A size of each agglomerate is not particularly limited as long as the size of the agglomerate is selected as appropriate such that the desired performance such as thermal conductivity is obtained in the finally resulting thermally conductive sheet. For example, the agglomerate can have an average particle diameter of about 20 μm or greater, about 40 μm or greater, about 60 μm or greater, or about 80 μm or greater. An upper limit value of the average particle diameter is not particularly limited, but can be defined as, for example, about 300 μm or less, about 250 μm or less, or about 200 μm or less, from the perspective of a resistance to dropping out from the thermally conductive sheet precursor or the like,

The size of the agglomerate can also be defined by D₅₀ (a particle diameter at a cumulative frequency of 50%) which is calculated from grain size distribution data. The D₅₀ of the agglomerates can be defined as about 20 μm or greater, about 40 μm or greater, or about 60 μm or greater, and can be defined as about 300 μm or less, about 250 μm or less, or about 200 μm or less.

The size of the agglomerate can also be defined by D₉₀ (a particle size at a cumulative frequency of 90%) which is calculated from the grain size distribution data. The D₉₀ of the agglomerates can be defined as about 30 μm or greater, about 50 μm or greater, or about 70 μm or greater, and can be defined as about 350 μm or less, about 300 μm or less, or about 250 μm or less.

An agglomerate having such a size is likely to be randomized after disintegration, and therefore, likely to exhibit the isotropic thermal conductivity to the thermally conductive sheet.

Here, the average particle diameters of the agglomerates, D₅₀ and D₉₀, can be determined using laser diffraction/scattering, or various microscopes such an optical microscopy, a scanning electron microscopy (SEM), and a transmission electron microscope (TEM), for example. In particular, it is preferable to use a volume average diameter obtained from grain size distribution measurement by laser diffraction (wet measurement, LS 13 320, from Beckman Coulter company).

In a case that the average particle diameter is determined using the microscope, an area circle-equivalent particle diameter of the agglomerates can be defined as the average particle diameter. For example, a particle size obtained by conversion into a circular particle having the same area as a projected area of the agglomerate observed by an electron microscopy can be intended. Such an area-equivalent particle diameter can be defined as an average value for 50 agglomerates.

Compounding Ratio of Agglomerates

A compounding ratio of the agglomerates is not particularly limited as long as the compounding ratio is adjusted as appropriate such that the desired performance such as thermal conductivity is obtained in the finally resulting thermally conductive sheet. For example, assuming that a combination of agglomerates, and an isotropic thermally conductive material and a filler of arbitrary components to be described later is defined as a “filler component”, in consideration of the thermal conductivity, mechanical strength, and the like, such filler component can be compounded in the thermally conductive sheet precursor at about 45 vol % or greater, about 50 vol % or greater, or about 55 vol % or greater, and can be compounded by about 80 vol % or less, about 75 vol % or less, or 70 vol % or less. Because the thermally conductive sheet of the present disclosure is formed using specific agglomerates and isotropic thermally conductive material, isotropic thermal conductivity can be sufficiently expressed even if the filler component is not filled by about as much as 90 vol %. Here, void spaces are included in the thermally conductive sheet precursor, the agglomerates prior to disintegration, and the like, but because a true density of each material is used in calculating the volume %, no void space is included in the value of the volume % described above.

A radio of the agglomerates in the filler component can be about 20% or higher, about 25% or higher, or about 30% or higher, and can be about 95% or lower, about 90% or lower, about 85% or lower, or about 80% or lower. Here, the ratio of the agglomerates can be calculated from an amount (vol %) of the agglomerates relative to a total amount (vol %) of the filler component. The thermally conductive sheet precursor including the agglomerates at such a compounding ratio can further improve the isotropic thermal conductivity of the finally resulting thermally conductive sheet.

Anisotropic Thermally Conductive Primary Particles

The primary particles constituting the agglomerates are not particularly limited as long as they are primary particles exhibiting anisotropic thermal conductivity. For example, inorganic primary particles having a needlelike, flattened, or scaly shape can be used alone or in combination of two or more types. Examples of the material constituting the inorganic primary particles include at least one selected from aluminum nitride, silicon nitride, and boron nitride. Among these, boron nitride is preferable, and scaly hexagonal boron nitride (h-BN) is more preferable because good insulation properties and the like can be imparted in addition to good thermal conductivity after the agglomerate disintegration.

A size of each primary particle constituting the agglomerates is not particularly limited as long as the size of the agglomerate is selected as appropriate such that the desired performance such as thermal conductivity is obtained in the finally resulting thermally conductive sheet. For example, an average long diameter or average particle diameter of the primary particles can be defined as about 1.5 μm or greater, about 2.0 μm or greater, or about 2.5 μm or greater, and can be defined as about 25 μm or less, about 20 μm or less, or about 15 μm or less.

The size of the primary particle can also be defined by D₅₀ calculated from the grain size distribution data. The D₅₀ of the primary particles can be defined as about 1.5 μm or greater, about 2.0 μm or greater, or about 2.5 μm or greater, and can be defined to be about 25 μm or less, about 20 μm or less, or about 15 μm or less.

The size of the primary particle can also be defined by D₉₀ calculated from the grain size distribution data. The D₉₀ of the primary particle can be defined as about 2.5 μm or greater, about 3.0 μm or greater, or about 3.5 μm or greater, and can be defined to be about 50 μm or less, about 45 μm or less, or about 40 μm or less.

Primary particles having such a size are likely to be randomized after disintegration of the agglomerates, and therefore, likely to exhibit the isotropic thermal conductivity to the thermally conductive sheet.

Here, the average long diameter of the primary particles can be determined using various microscopes such as an optical microscopy, a scanning electron microscopy (SEM), a transmission electron microscope (TEM), for example, and the average particle diameter of the primary particles, the D₅₀ and the D₉₀, can be determined using laser diffraction/scattering, for example. Here, in a case that the average long diameter is determined using a microscope, the average long diameter can be defined as an average value for 50 primary particles.

Isotropic Thermally Conductive Material

The isotropic thermally conductive material contained in the thermally conductive sheet precursor of the present disclosure is not particularly limited as long as it is different from the aforementioned agglomerates and has an average particle diameter of about 20 μm or greater. For example, the isotropic thermally conductive material that does not disintegrate against the first pressure applied to the thermally conductive sheet precursor can be used. Specifically, for example, substantially spherical inorganic primary particles or agglomerates can be used alone or in combination of two or more types. Examples of the material constituting the inorganic primary particles or agglomerates include at least one selected from aluminum nitride, aluminum oxide, silicon carbide, and boron nitride. Among these, aluminum nitride, aluminum oxide, or boron nitride is preferable, aluminum nitride or aluminum oxide is more preferable, and aluminum oxide is particularly preferable, from the perspective of the thermal conductivity, insulating properties, manufacturing costs, and the like.

Here, the substantially spherical form can be defined by, for example, a degree of circularity (4π×area/square of circumferential length), and those having a degree of circularity in a range from about 0.7 to about 1.0 can be defined as being substantially spherical.

The substantially spherical inorganic agglomerates that do not disintegrate at the first pressure applied to the thermally conductive sheet precursor can be appropriately prepared, for example, by sintering, at a high temperature, agglomerates in which the aforementioned anisotropic thermally conductive primary particles are agglomerated.

Size of Isotropic Thermally Conductive Material

The isotropic thermally conductive material is not particularly limited as long as the material has an average particle diameter of about 20 μm or greater, but from the perspective of the thermal conductivity and the like, the average particle diameter is preferably about 30 μm or greater, or 40 μm or greater. An upper limit value of the average particle diameter is not particularly limited, but can be defined as, for example, about 200 μm or less, about 150 μm or less, or about 100 μm or less, from the perspective of a resistance to dropping out from the thermally conductive sheet precursor or the like.

The size of the isotropic thermally conductive material can also be defined by D₅₀ calculated from the grain size distribution data. The D₅₀ of the isotropic thermally conductive material can be defined as about 30 μm or greater, about 40 μm or greater, or about 50 μm or greater, and can be defined as about 200 μm or less, about 150 μm or less, or about 100 μm or less.

The isotropic thermally conductive material having such a size has a smaller ratio of an interface to a binder resin, in which an isotropic thermally conductive path is easily obtained, and therefore, likely to exhibit the isotropic thermal conductivity to the thermally conductive sheet.

Here, the average particle diameter and D₅₀ of the isotropic thermally conductive material can be determined using laser diffraction/scattering, or various microscopes such an optical microscopy, a scanning electron microscopy (SEM), and a transmission electron microscope (TEM), for example. In particular, it is preferable to use a volume average diameter obtained from grain size distribution measurement by laser diffraction (wet measurement, LS 13 320, from Beckman Coulter company).

In a case that the average particle diameter is determined using the microscope, an area circle-equivalent particle diameter of the isotropic thermally conductive material can be defined as the average particle diameter. For example, a particle size obtained by conversion into a circular particle having the same area as a projected area of the isotropic thermally conductive material observed by a microscopy can be intended. Such an area-equivalent particle diameter can be defined as an average value for 50 isotropic thermally conductive materials.

Compounding Ratio of Isotropic Thermally Conductive Material

A compounding ratio of the isotropic thermally conductive material is not particularly limited as long as the compounding ratio is adjusted as appropriate such that the desired performance such as thermal conductivity is obtained in the finally resulting thermally conductive sheet. For example, a ratio of the isotropic thermally conductive material in the filler component is about 5% or higher, about 10% or higher, about 15% or higher, about 20% or higher, about 25% or higher, about 30% or higher, about 35% or higher, or about 40% or higher, and can be about 80% or lower, about 75% or lower, about 70% or lower, about 65% or lower, or about 60% or lower. Here, the ratio of the agglomerates can be calculated from an amount (vol %) of the isotropic thermally conductive material relative to a total amount (vol %) of the filler component. The thermally conductive sheet precursor including the isotropic thermally conductive material at such a compounding ratio can further improve the thermal conductivity of the finally resulting thermally conductive sheet.

Binder Resin

The binder resin included in the thermally conductive sheet precursor of the present disclosure can be selected as appropriate in accordance with the use of the finally resulting thermally conductive sheet, and is not particularly limited. For example, the thermoplastic resin, a thermosetting resin, a rubber resin, or the like can be used alone or in combination of two or more types.

Examples of the thermoplastic resin can include polyolefin resins such as polyethylene and polypropylene, polyester resins such as polyethylene terephthalate and polyethylene naphthalate, polycarbonate resins, polyamide resins, and polyphenylene sulfide resins.

Examples of the thermosetting resin can include epoxy resins, (meth)acrylic resins, urethane resins, silicone resins, unsaturated polyester resins, phenol resins, melamine resins, and polyimide resins. Among these, epoxy resins are preferable from the perspective of formability of the thermally conductive sheet, adhesion with other members, insulation properties, and the like. Examples of the epoxy resin include bisphenol-A epoxy resins, bisphenol-F epoxy resins, ortho-cresol novolac epoxy resins, phenol novolac epoxy resins, alicyclic aliphatic epoxy resins, and glycidyl-aminophenol epoxy resins.

Examples of the rubber resin can include silicone rubber, isoprene rubber, butadiene rubber, styrene butagen rubber, chloroprene rubber, ethylene propylene rubber, ethylene-propylene-diene rubber, nitrile rubber, acrylonitrile butadiene rubber (NBR), hydrogenated NBR, acrylic rubber, urethane rubber, fluorine rubber, and natural rubber.

Compounding Ratio of Binder Resin

A compounding ratio of the binder resin is not particularly limited as long as the compounding ratio is adjusted as appropriate such that the desired performance (thermal conductivity, insulating properties, and the like) in accordance with the use of the finally resulting thermally conductive sheet is obtained. For example, the binder resin can be compounded in the thermally conductive sheet precursor at about 20 vol % or more, about 25 vol % or more, or about 30 vol % or more, and is about 80 vol % or less, about 75 vol % or less, about 70 vol % or less, about 65 vol % or less, about 60 vol % or less, about 55 vol % or less, about 50 vol % or less, or about 45 vol % or less. The thermally conductive sheet precursor including the binder resin at such a compounding ratio can further improve the performance such as the thermal conductivity, insulating properties, and mechanical strength of the finally resulting thermally conductive sheet. Here, void spaces are included in the thermally conductive sheet precursor, the agglomerates prior to disintegration, and the like, but because a true density of each material is used in calculating the volume %, no void space is included in the value of the volume % described above.

Optional Additive Materials

The thermally conductive sheet precursor of the present disclosure may further include additives such as flame retardants, pigments, dyes, fillers, reinforcing materials, leveling agents, coupling agents, anti-foaming agents, dispersants, heat stabilizers, photostabilizers, crosslinkers, thermo-curing agents, light-curing agents, curing accelerators, tackifiers, plasticizers, reactive diluents, solvents, and the like. A compounded amount of these additives can be appropriately determined within a range that does not impair the effects of the present disclosure.

Filler

For example, various thermally conductive materials (for example, anisotropic thermally conductive materials, isotropic thermally conductive materials) other than the aforementioned agglomerates and isotropic thermally conductive materials can be used as the filler. That is, for example, a thermally conductive material or the like that is present separately from the anisotropic thermally conductive primary particles constituting the agglomerates can be used as the filler. Such a filler is easily disposed between the disintegrated agglomerates or the like and is excellent in properties of filling (packing properties) the void spaces or the like present between the agglomerates, and therefore, can improve the thermal conductivity and insulating properties of the finally resulting thermally conductive sheet.

Examples of the filler of the present disclosure can include at least one selected from inorganic primary particles of aluminum nitride, silicon nitride, boron nitride, silicon carbide, aluminum oxide (alumina), and the like having a spherical, needlelike, flattened, or scaly shape, and secondary particles in which such inorganic primary particles are agglomerated. Among these, from the perspective of the thermal conductivity and insulating properties of the finally resulting thermally conductive sheet, primary particles or secondary particles of boron nitride, in particular, scaly hexagonal boron nitride (h-BN), are preferable. Here, the secondary particles in which the inorganic primary particles are agglomerated to exhibit anisotropic thermal conductivity are as those disclosed in, for example, U.S. Patent Application No. 2012/0114905, and such secondary particles can be produced by applying boron nitride inorganic primary particles or the like between two rolls rotating in two different directions to press and solidify the particles.

Size of Filler

A size of the filler of the present disclosure is not particularly limited, and can be, for example, an average long diameter or average particle diameter of the filler can be about 1.0 μm or greater, about 1.5 μm or greater, or about 2.0 μm or greater, and can be about 25 μm or less, about 20 μm or less, about 15 μm or less, about 10 μm or less, about 9.0 μm or less, about 8.5 μm or less, or about 8.0 μm or less.

The size of the filler can also be defined by D₅₀ calculated from the grain size distribution data. The D₅₀ of the filler can be defined as about 1.0 μm or greater, about 1.5 μm or greater, or about 2.0 μm or greater, and can be defined as about 25 μm or less, about 20 μm or less, or about 15 μm or less.

The size of the filler can also be defined by D₉₀ calculated from the grain size distribution data. The D₉₀ of the filler can be defined as about 2.5 μm or greater, about 3.0 μm or greater, or about 3.5 μm or greater, and can be defined to be about 50 μm or less, about 45 μm or less, or about 40 μm or less.

In particular, in a case that the size of the filler is smaller than the size of the anisotropic thermally conductive primary particles constituting the agglomerates described above, the filler is easier to fill between the disintegrated agglomerates and the like, and therefore, can further improve the performance such as the thermal conductivity and insulating properties of the finally resulting thermally conductive sheet.

When the agglomerates disintegrate, a pressure is simultaneously applied also to the filler by the anisotropic thermally conductive primary particles constituting such agglomerates, for example. As a result, the filler of a portion to which the pressure is applied is densified. In a case that the filler is of an anisotropic thermally conductive material, the filler is likely to be oriented in a different direction rather than in a horizontal direction with respect to the thermally conductive sheet, and therefore, the resulting thermally conductive sheet more easily exhibits the isotropic thermal conductivity and improves the insulating properties.

Here, the average long diameter of the filler can be determined using various microscopes such as an optical microscopy, a scanning electron microscopy (SEM), a transmission electron microscope (TEM), for example, and the average particle diameter of the filler, the D₅₀ and the D₉₀, can be determined using laser diffraction/scattering, for example. Here, in a case that the average long diameter is determined using a microscope, the average long diameter can be defined as an average value for 50 fillers.

Compounding Ratio of Filler

A compounding ratio of the filler is not particularly limited as long as the compounding ratio is adjusted as appropriate such that the desired performance (thermal conductivity, insulating properties, and the like) in accordance with the use of the finally resulting thermally conductive sheet is obtained. For example, a ratio of the filler in the filler component can be about 1% or higher, about 3% or higher, or about 5% or hgher, and can be about 20% or lower, about 17% or lower, or about 15% or lower. Here, the ratio of the filler can be calculated from an amount (vol %) of the filler relative to a total amount (vol %) of the filler component. The thermally conductive sheet precursor including the filler at such a compounding ratio can further improve the thermal conductivity and insulating properties of the finally resulting thermally conductive sheet.

Thickness of Thermally Conductive Sheet Precursor

A thickness of the thermally conductive sheet precursor of the present disclosure is not particularly limited as long as the thickness may be adjusted as appropriate in accordance with the use or the like of the finally resulting thermally conductive sheet. For example, the thermally conductive sheet precursor can have a thickness larger than the maximum value of short axis lengths (a length of the smallest side) of the agglomerates described above. Such a thickness can reduce defects such as the agglomerate dropping-out.

Here, the short axis length of the agglomerate can be determined by, for example, capturing an image of the agglomerate by an optical microscope to obtain data of the captured image, and then, using the particle analysis function of the ImageJ software (version 1.50i) for the captured image data, where the short axis length is determined as a short axis diameter obtained from the ellipse approximation. The maximum value of the short axis lengths of the agglomerates can be defined as a maximum value among short axis lengths of 100 agglomerates which are determined.

Thermally Conductive Sheet

The thermally conductive sheet obtained from the thermally conductive sheet precursor of the present disclosure is excellent in the isotropic thermal conductivity and can arbitrarily exhibit the insulating properties.

Characteristics of Thermally Conductive Sheet

Thermal Conductivity Rate

The thermally conductive sheet obtained from the thermally conductive sheet precursor of the present disclosure can have a thermal conductivity rate of, for example, about 4.5 W/m·K or greater, and about 5.0 W/m·K or greater, about 5.5 W/m·K or greater, about 6.0 W/m·K or greater, about 6.5 W/m·K or greater, or about 7.0 W/m·K or greater, although varying depending on the compounded amount of the filler component or the like. An upper limit value of the thermal conductivity rate is not particularly limited, but can be defined as, for example, about 20 W/m·K or lower, about 18 W/m·K or lower, or about 15 W/m·K or lower. The thermally conductive sheet having such a thermal conductivity rate can be sufficiently used for the power modules and the like of electric vehicles (EV), for example. Here, thermal conductivity rate measurement can be determined by, for example, a thermal conductivity rate test in Examples described below. Because such tests examine the thermal conductivity from a bottom surface to a top surface of the thermally conductive sheet, an obtained thermal conductivity rate is an indicator of isotropic thermal conductivity.

Insulation Breakdown Voltage

The thermally conductive sheet obtained from the thermally conductive sheet precursor of the present disclosure can have an insulation breakdown voltage of about 10 kv/mm or greater, about 11 kV/mm or greater, or about 12 kV/mm or greater. An upper limit value of the insulation breakdown voltage is not particularly limited, but can be defined as, for example, about 50 kV/mm or less, about 45 kV/mm or less, or about 40 kV/mm or less. The thermally conductive sheet having such an insulation breakdown voltage is excellent in the insulating properties, and therefore, can be sufficiently used for the power modules and the like of electric vehicles (EV), for example.

Here, the insulation breakdown voltage of the thermally conductive sheet can be measured using, for example, a puncture tester (TP-5120A) available from Asao electrons Co., Ltd. The value of the insulation breakdown voltage in this case is an average value obtained by performing measurement three times at a rate of 0.5 kV/s under an atmospheric atmosphere at different spots of the measurement sample.

Thickness of Thermally Conductive Sheet

A thickness of the thermally conductive sheet of the present disclosure is not particularly limited as long as the thickness may be adjusted as appropriate in accordance with the use or the like of the finally resulting thermally conductive sheet. For example, the thickness of the thermally conductive sheet can be about 80 μm or greater, about 100 μm or greater, or about 150 μm or greater, and can be about 400 μm or less, about 350 μm or less, or about 300 μm or less.

Method of Manufacturing Thermally Conductive Sheet

The thermally conductive sheet of the present disclosure can be manufactured by, for example, the following method.

In a given container, a binder resin, a solvent, and optionally a curing agent and the like are blended, and stirred at about 1000 to 3000 rpm for about 10 to 60 seconds using a high-speed mixer or the like, to prepare a mixture A. Next, the mixture A is then further blended with agglomerates, an isotropic thermally conductive material, optionally a filler, and optionally a solvent, and stirred at about 1000 to 3000 rpm for about 10 to 60 seconds using a high-speed mixer or the like, to prepare a mixture B. Next, the mixture B is applied on a release liner using known coating means such as a bar coater and a knife coater, and dried under predetermined conditions, and then a thermally conductive sheet precursor can be obtained.

Drying may be one step of drying, but may be two or more steps of drying, in which drying at about 50 to 70° C. for about 1 to 10 minutes may be performed, and then, drying at about 80 to 120° C. for about 10 minutes may be performed, for example. Through such multi-step drying, a thermally conductive sheet precursor having void spaces as illustrated in FIG. 1(a) is likely to be obtained.

Next, a predetermined pressure is applied to the resulting thermally conductive sheet precursor at about 50 to 70° C. for about 1 to 10, and then, a thermally conductive sheet as illustrated in FIG. 2(a) can be manufactured. Such a pressure can be set as appropriate in consideration of the disintegrability of the agglomerates and can be at least about 0.75 MPa, at least about 1.0 MPa, or at least about 3.0 MPa, and can be about 12 MPa or less, about 10 MPa or less, or about 8.0 MPa or less.

Here, in a case that a thermo-curing agent is used, curing may be performed using the heat of the drying step described above, and may be performed separately in other steps such as the pressure applying step and additional heating steps.

The thermally conductive sheet obtained by such a method can have at least one or more potions where a plurality of anisotropic thermally conductive primary particles disintegrating from the agglomerates (sometimes referred to simply as “disintegrated primary particles”) locally congregate in a circular region of about 20 to about 150 μm diameter in a cross section in the thickness direction, as illustrated in FIG. 2(a). The diameter of such a circular region can be about 20 μm or more, about 25 μm or more, or about 30 μm or more, and can be about 150 μm or less, about 120 μm or less, or about 100 μm or less. Here, “the potion where a plurality of disintegrated primary particles locally congregate” can refer to a portion where no isotropic thermally conductive material is present and a plurality of anisotropic thermally conductive primary particles disintegrating from the agglomerates congregate.

In the case of a thermally conductive sheet obtained from a material in which a binder resin, anisotropic thermally conductive primary particles, and isotropic thermally conductive material are simply blended, the anisotropic thermally conductive primary particles and the isotropic thermally conductive material are mixed so as to be uniformly dispersed, so it is thought that the portion where a plurality of disintegrated primary particles locally congregate as described above is not formed.

The thermally conductive sheet of the present disclosure obtained by applying a predetermined pressure can have, around the isotropic thermally conductive material, particles resulting from a plurality of anisotropic thermally conductive primary particles constituting the agglomerates being finely broken (sometimes referred to simply as “broken particles”) as illustrated in FIG. 2(a).

It is thought that particles that are broken by applying a predetermined pressure are likely to be oriented in a random direction, and therefore, likely to exhibit isotropic thermal conductivity with respect to the thermally conductive sheet.

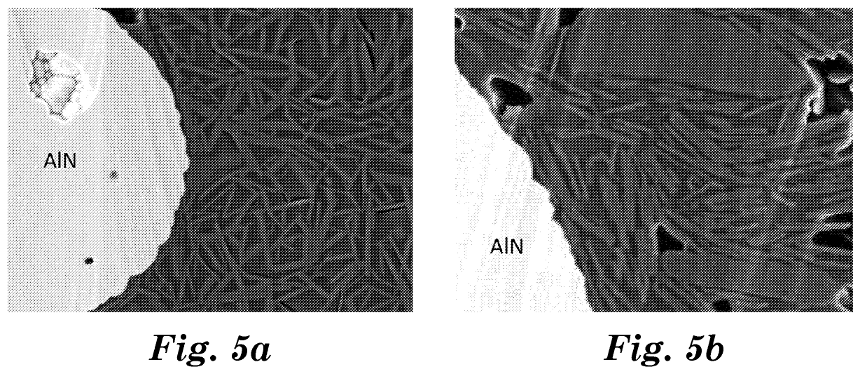

One of factors by which such broken particles are formed can be thought to be that, for example, in a case that a hardness of the isotropic thermally conductive material is greater than a hardness of the anisotropic thermally conductive primary particles constituting the agglomerates, the primary particles present around the isotropic thermally conductive material are likely to be broken under pressure received from the isotropic thermally conductive material. On the other hand, in the case of a thermally conductive sheet obtained from a material in which the binder resin, the anisotropic thermally conductive primary particles, and the isotropic thermally conductive material are simply blended, since the sheet is not affected by pressure when forming the sheet, the finely broken anisotropic thermally conductive primary particles are not formed around the isotropic thermally conductive material, as illustrated in FIG. 5(b).

Use of Thermally Conductive Sheet

The thermally conductive sheet of the present disclosure may be used as a heat-dissipating article which is used for, for example, a means of transport such as an electric vehicle (EV), a consumer electronic product, a computer device, or the like, in particular used for a power module, and is disposed to fill a space between a heat generating component such as an IC chip and a heat dissipating component such as a heat sink or a heat pipe so that heat generated from the heat generating component is efficiently transferred to the heat dissipating component.

The thermally conductive sheet of the present disclosure can also impart adhesion by appropriately selecting a binder resin. For example, in a case that an epoxy resin is used as the binder resin, the thermally conductive sheet of the present disclosure can be used as a heat adhesion type thermally conductive adhesive sheet.

### EXAMPLES

### Examples 1 to 6 and Comparative Examples 1 to 2

Although specific embodiments of the present disclosure will be exemplified in the following Examples, the present disclosure is not limited to these embodiments.

The products and the like used in Examples are illustrated in Table 1 below.

TABLE 1

| Trade name, | | |
|---|---|---|
| model number | | |
| or abbreviation | Description | Provider |
| NPEL-128 | Bisphenol-a epoxy resin | NANYA Company |
| | | (TAIWAN) |
| YDCN-700-3 | Ortho-cresol novolac epoxy resin | Nippon Steel & Sumikin |
| | | Chemical Co., Ltd. |
| | | (Chiyoda-ku, Tokyo, |
| | | Japan) |
| DICYANEX (™) | Curing agent: dicyandiamide | Evonik Japan Co., Ltd. |
| 1400F | | (Shinagawa-ku, Tokyo, |
| | | Japan) |
| 3M (™) boron | Isotropic thermally conductive | 3M Japan Ltd. |
| nitride cooling filler | agglomerates in which scaly (plate- | (Shinagawa-ku, Tokyo, |
| A type agglomerate | like) boron nitride primary particles | Japan) |
| 50 (A50) | are agglomerated. Average particle | |
| | diameter: 26.7 μm, particle diameter | |
| | (D₅₀): 23.0 μm, particle diameter | |
| | (D₉₀): 46.8 μm | |
| 3M (™) boron | Isotropic thermally conductive | 3M Japan Ltd. |
| nitride cooling filler | agglomerates in which scaly (plate- | (Shinagawa-ku, Tokyo, |
| A type agglomerate | like) boron nitride primary particles | Japan) |
| 150 (A150) | are agglomerated. Average particle | |
| | diameter: 100.1 μm, particle diameter | |
| | (D₅₀): 97.7 μm, particle diameter | |
| | (D₉₀): 147.5 μm | |
| FAN-fO5 (F05) | Aluminum nitride particles having a | Furukawa Denshi Co., |
| | particle diameter (D₅₀) of 3.7 μm | Ltd. (Iwaki-shi, |
| | | Fukushima, Japan) |
| FAN-f30 (F30) | Sintered aluminum nitride particles | Furukawa Denshi Co., |
| | having particle diameter (D₅₀) of 31.3 | Ltd. (Iwaki-shi, |
| | μm | Fukushima, Japan) |
| FAN-f50 (F50) | Sintered aluminum nitride particles | Furukawa Denshi Co., |
| | having particle diameter (D₅₀) of 54.7 | Ltd. (Iwaki-shi, |
| | μm | Fukushima, Japan) |
| FAN-f80 (F80) | Sintered aluminum nitride particles | Furukawa Denshi Co., |
| | having particle diameter (D50) of | Ltd. (Iwaki-shi, |
| | 84.1 μm | Fukushima, Japan) |
| CB-A50S | Aluminum oxide particles having | Showa Denko K.K. |
| | particle diameter (D₅₀) OF 49.8 μm | (Shinagawa-ku, Tokyo, |
| | | Japan) |
| 3M (™) boron | Scaly (plate-like) boron nitride | 3M Japan Ltd. |
| nitride cooling filler | primary particles having average long | (Shinagawa-ku, Tokyo, |
| P type platelet 003 | diameter of 3 μm. Particle diameter | Japan) |
| (P003) | (D₅₀): 4.1 μm, Particle diameter | |
| | (D₉₀): 11.0 μm, aspect ratio 2.1 | |
| 3M (™) boron | Scaly (plate-like) boron nitride | 3M Japan Ltd. |
| nitride cooling filler | primary particles having average long | (Shinagawa-ku, Tokyo, |
| P type platelet 015 | diameter of 15 μm. | Japan) |
| (P015) | Particle diameter (D₅₀): 13.8 μm, | |
| | particle diameter (D₉₀): 28.5 μm, | |
| | aspect ratio 2.1 | |
| MEK | Methyl ethyl ketone | Wako Pure Chemical |
| | | Industries, Ltd. (Chuo- |
| | | ku, Osaka, Japan) |

The materials illustrated in Table 1 were mixed at the compounding ratios illustrated in Tables 2 and 3, and coating liquids for fabricating the thermally conductive sheet precursor were created. Here, numerical values for the binder resin, the fillers A and B, the solvent, and the total amount in Tables 2 and 3 are all in units of parts by mass. The filler A refers to the agglomerate or a filler, and the filler B refers to an isotropic thermally conductive material. A filler ratio (%) refers to a ratio of each filler in the filler component included in the thermally conductive sheet, and can be calculated as a percentage of a filler amount (vol %) relative to a filler component amount (vol %).

TABLE 2

| | | Thermally conductive sheet precursor coating liquid | | | | | | | | | |
|---|---|---|---|---|---|---|---|---|---|---|---|
| | | Example 1 (F30/A50) | | | | | Example 2 (F50/A50) | | | | |
| | | t-0 | TA-1 | TA-2 | TA-3 | ta-4 | t-0 | TB-t | TB-2 | TB-3 | tb-4 |
| Binder | NPEL-128 | 10 | 10 | 10 | 10 | 10 | 10 | 10 | 10 | 10 | 10 |
| resin | YDCN- | 90 | 90 | 90 | 90 | 90 | 80 | 90 | 90 | 90 | 90 |
| | 700-3 | | | | | | | | | | |
| | DICYANEX | 8.1 | 8.1 | 8.1 | 8.1 | 8.1 | 8.1 | 8.1 | 8.1 | 3.1 | 8.1 |
| | 1400F | | | | | | | | | | |
| Filler | P003 | 0 | 0 | 0 | 0 | 0 | 0 | 0 | 0 | 0 | 0 |
| A | P015 | 0 | 0 | 0 | 0 | 0 | 0 | 0 | 0 | 0 | 0 |
| | AGO | 340 | 255 | 170 | 85 | 0 | 340 | 255 | 170 | 85 | 0 |
| | A150 | 0 | 0 | 0 | 0 | 0 | 0 | 0 | 0 | 0 | 0 |
| Filler B | FOB | 0 | 0 | 0 | 0 | 0 | 0 | 0 | 0 | 0 | 0 |
| | F30 | 0 | 121.26 | 242.5 | 363.75 | 485 | 0 | 0 | 0 | 0 | 0 |
| | F50 | 0 | 0 | 0 | 0 | 0 | 0 | 121.25 | 242.5 | 363.75 | 485 |
| | F80 | 0 | 0 | 0 | 0 | 0 | 0 | 0 | 0 | 0 | 0 |
| | CB-A5QS | 0 | 0 | 0 | 0 | 0 | 0 | 0 | 0 | 0 | 0 |
| Solvent | MEK | 320 | 225 | (50 | 70 | 50 | 320 | 225 | 150 | 70 | 50 |
| Total | | 768.1 | 709.35 | 670.6 | 626.85 | 643.1 | 768.1 | 709.35 | 670.6 | 626.85 | 643.1 |
| Filler component | | 60 | 90 | 60 | 60 | 60 | 60 | 60 | 60 | 60 | 60 |
| amount (vol %) | | | | | | | | | | | |
| Filler | P003 | | — | — | — | — | — | — | — | — | — |
| ratio | P0I5 | — | — | — | — | — | — | — | — | — | — |
| (%) | AGO | 100 | 75 | 50 | 25 | 0 | 100 | 75 | 50 | 25 | 0 |
| | A150 | — | | — | — | — | — | — | — | — | — |
| | F05 | — | — | — | — | — | — | — | — | — | — |
| | F30 | 0 | 25 | 50 | 75 | 100 | — | — | — | — | — |
| | F50 | — | — | — | — | — | 0 | 25 | 50 | 75 | 100 |
| | F80 | — | — | — | — | — | — | — | — | — | — |
| | CB-A50S | — | ″ | — | ″ | — | — | — | — | — | — |

Thermally conductive sheet precursor coating liquid
Example 3

| | | (F80/A50) | | | Example 4 (F50/A150) | | | | |
|---|---|---|---|---|---|---|---|---|---|
| | | t-0 | TC-1 | TC-2 | t-1 | TD-1 | TD-2 | TD-3 | td-4 |
| Binder | NPEL-128 | 10 | 10 | 10 | 10 | 10 | 10 | 10 | 10 |
| resin | YDCN- | 90 | 90 | 90 | 90 | 90 | 90 | 90 | 90 |
| | 700-3 | | | | | | | | |
| | DICYANEX | 8.1 | 8.1 | 8.1 | 8.1 | 8.1 | 8.1 | 8.1 | 8.1 |
| | 1400F | | | | | | | | |
| Filler | P003 | 0 | 0 | 0 | 0 | 0 | 0 | 0 | 0 |
| A | P015 | 0 | 0 | 0 | 0 | 0 | 0 | 0 | 0 |
| | AGO | 340 | 255 | 170 | 0 | 0 | 0 | 0 | 0 |
| | A150 | 0 | 0 | 0 | 340 | 255 | 170 | 85 | 0 |
| Filler B | FOB | 0 | 0 | 0 | 0 | 0 | 0 | 0 | 0 |
| | F30 | 0 | 0 | 0 | 0 | 0 | 0 | 0 | 0 |
| | F50 | 0 | 0 | 0 | 0 | 121.25 | 242.5 | 363.75 | 485 |
| | F80 | 0 | 121.25 | 242.5 | 0 | 0 | 0 | 0 | 0 |
| | CB-A5QS | 0 | 0 | 0 | 0 | 0 | 0 | 0 | 0 |
| Solvent | MEK | 320 | 225 | 150 | 320 | 225 | 150 | 70 | 50 |
| Total | | 768.1 | 709.35 | 670.6 | 768.1 | 709.35 | 670.6 | 626.85 | 643.1 |
| Filler component | | 60 | 60 | 60 | 60 | 60 | 60 | 60 | 60 |
| amount (vol %) | | | | | | | | | |
| Filler | P003 | — | — | — | — | — | — | — | — |
| ratio | P0I5 | — | — | — | — | — | — | — | — |
| (%) | AGO | 100 | 75 | 50 | — | — | — | — | — |
| | A150 | — | — | — | 100 | 75 | 50 | 25 | 0 |
| | F05 | — | — | — | — | — | — | — | — |
| | F30 | — | — | — | — | — | — | — | — |
| | F50 | — | — | — | 0 | 25 | 50 | 75 | 100 |
| | F80 | 0 | 25 | 50 | — | — | — | — | — |
| | CB-A50S | — | — | — | — | — | — | — | — |

TABLE 3

| | | Thermally conductive sheet precursor coating liquid | | | | | | | | | |
|---|---|---|---|---|---|---|---|---|---|---|---|
| | | Example 5 | | | | | Example 6 | | | | |
| | | (F50/A150/P003) | | | | | (CB-A50S/A50) | | | | |
| | | t-2 | TE 1 | TE-2 | TE-3 | te-4 | t-0 | TF-1 | TF-2 | TF-3 | tf-4 |
| Binder | NPEL- | 10 | 10 | 10 | 10 | 10 | 10 | 10 | 10 | 10 | 10 |
| resin | 128 | | | | | | | | | | |
| | YDCN- | 90 | 90 | 90 | 90 | 90 | 90 | 90 | 90 | 90 | 90 |
| | 700-3 | | | | | | | | | | |
| | DICYA | 8.1 | 8.1 | 8.1 | 8.1 | 8.1 | 8.1 | 8.1 | 8.1 | 8.1 | 8.1 |
| | NEX | | | | | | | | | | |
| | HOOF | | | | | | | | | | |
| Filler A | P003 | 51 | 38.25 | 25.5 | 12.75 | 0 | 0 | 0 | 0 | 0 | 0 |
| | P015 | 0 | 0 | O | 0 | 0 | 0 | 0 | 0 | 0 | 0 |
| | A50 | O | 0 | O | 0 | 0 | 340 | 255 | 170 | 85 | 0 |
| | A150 | 289 | 216.75 | 144.5 | 72.25 | 0 | 0 | 0 | 0 | 0 | 0 |
| Filler B | F05 | 0 | 0 | 0 | 0 | 0 | 0 | 0 | 0 | 0 | 0 |
| | F30 | 0 | 0 | 0 | 0 | 0 | 0 | 0 | 0 | 0 | 0 |
| | F60 | 0 | 121.25 | 242.5 | 363.75 | 435 | 0 | 0 | 0 | 0 | 0 |
| | F80 | 0 | 0 | 0 | 0 | 0 | 0 | 0 | 0 | 0 | 0 |
| | CB- | 0 | 0 | 0 | 0 | 0 | 0 | 145 | 290 | 435 | 580 |
| | A50S | | | | | | | | | | |
| Solvent | MEK | 320 | 225 | 150 | 70 | 50 | 320 | 275 | 175 | 75 | 50 |
| Total | | 768.1 | 768.1 | 709.35 | 670.6 | 626.85 | 643.1 | 709.35 | 670.6 | 626.85 | 643.1 |
| Filler component | | 60 | 60 | 60 | 60 | 60 | 60 | 60 | 60 | 60 | 60 |
| amount (vol %) | | | | | | | | | | | |
| Filler | P003 | 15 | 11.25 | 7.5 | 3.75 | 0 | — | — | — | — | — |
| ratio | P015 | — | — | — | — | — | — | — | — | — | — |
| | A50 | — | — | — | — | — | 100 | 75 | 50 | 25 | 0 |
| | A150 | 85 | 63.75 | 42.5 | 21.25 | 0 | — | — | — | — | — |
| | F05 | — | — | — | — | — | — | — | — | — | — |
| | F30 | — | — | — | — | — | — | — | — | — | — |
| | F50 | 0 | 25 | 50 | 75 | too | — | — | — | — | — |
| | F80 | — | | — | — | — | — | — | — | — | — |
| | CB- | | — | — | — | — | 0 | 25 | 50 | 75 | 100 |
| | A50S | | | | | | | | | | |
| | | Thermally conductive sheet precursor coating liquid | | | | | | | | | |
| | | Comparative example 1 | | | | | Comparative example 2 | | | | |
| | | (F05/A50) | | | | | (F50/P015) | | | | |
| | | t-0 | C-1 | C-2 | C-3 | C-4 | t-3 | D-1 | D-2 | D-3 | D-4 |
| Binder | NPEL- | 10 | 10 | 10 | 10 | 10 | 10 | 10 | 10 | 10 | 10 |
| resin | 128 | | | | | | | | | | |
| | YDCN- | 90 | 90 | 90 | 90 | 90 | 90 | 90 | 90 | 90 | 90 |
| | 700-3 | | | | | | | | | | |
| | DICYA | 8.1 | 8.1 | 8.1 | 8.1 | 8.1 | 3.1 | 8.1 | 8.1 | 8.1 | 8.1 |
| | NEX | | | | | | | | | | |
| | HOOF | | | | | | | | | | |
| Filler A | P003 | 0 | 0 | 0 | 0 | 0 | 0 | 0 | 0 | 0 | 0 |
| | P015 | 0 | 0 | 0 | 0 | 0 | 340 | 255 | 170 | 85 | 0 |
| | A50 | 340 | 255 | 170 | 85 | 0 | 0 | 0 | 0 | 0 | 0 |
| | A150 | 0 | 0 | 0 | 0 | 0 | 0 | 0 | 0 | 0 | 0 |
| Filler B | F05 | 0 | 121.25 | 242.5 | 363.75 | 485 | O | 0 | 0 | 0 | 0 |
| | F30 | 0 | 0 | 0 | O | 0 | 0 | 0 | 0 | 0 | 0 |
| | F60 | 0 | 0 | 0 | 0 | 0 | 0 | 121.25 | 242.5 | 363.75 | 485 |
| | F80 | 0 | 0 | 0 | 0 | 0 | 0 | 0 | 0 | 0 | 0 |
| | CB- | 0 | 0 | 0 | 0 | 0 | 0 | 0 | 0 | 0 | 0 |
| | A50S | | | | | | | | | | |
| Solvent | MEK | 320 | 225 | 150 | 70 | 50 | 320 | 225 | 150 | 70 | 50 |
| Total | | 768.1 | 768.1 | 709.35 | 670.6 | 626.85 | 768.1 | 709.35 | 670.6 | 626.85 | 643.1 |
| Filler component | | 60 | 60 | 60 | 60 | 60 | 60 | 60 | 60 | 60 | 60 |
| amount (vol %) | | | | | | | | | | | |
| Filler | P003 | — | — | — | — | — | — | — | — | — | — |
| ratio | P015 | — | — | — | — | — | 100 | 75 | 50 | 25 | 0 |
| | A50 | 100 | 75 | 50 | 25 | 0 | — | — | — | — | — |
| | A150 | — | — | — | — | — | — | — | — | — | — |
| | F05 | 0 | 25 | 50 | 75 | 100 | — | — | — | — | — |
| | F30 | — | — | — | — | — | — | — | — | — | — |
| | F50 | — | — | — | — | — | 0 | 25 | 50 | 75 | 100 |
| | F80 | — | — | — | — | — | — | — | — | — | — |
| | CB- | — | — | — | — | — | — | — | — | — | — |
| | A50S | | | | | | | | | | |

Evaluation Test

Properties and Internal Structure of the Thermally Conductive Sheet were Evaluated Using the Following Method.

Thermal Conductivity Rate Test

A thermal diffusivity is measured as follows using flash analysis methods by Hyper Flash™ LFA 467, available from Netzsch company. A thermally conductive sheet precursor which is applied between two release liners is placed in a hot press machine (heater plate press device N5042-00, available from NPa System Co., Ltd), in which the precursor is cured by applying a predetermined pressure at 180° C. for 30 minutes to fabricate a sample A of a thermally conductive sheet having a thickness of 200 to 300 μm. Next, the sample A is cut into pieces each having a size 10 mm×10 mm using a knife cutter to fabricate a sample B and the sample B is attached into a sample holder. Before measurement, both sides (top and bottom surfaces) of the sample B are coated with a thin layer of graphite (GRAPHIT33 from Kontakt Chemie) to fabricate a sample C. In the measurement, after the bottom surface is irradiated with a light pulse (by a xenon flash lamp, 230 V, a duration of 20 to 30 μs), a temperature of the top surface of the sample C is measured by an InSbIR detector. Next, a thermal diffusivity is calculated from a thermogram fit using a cowon method. The measurement is performed on the sample C three times at 23° C. For each coating agent formulation, four samples are prepared and measured. The thermal conductivity rate is calculated using Proteus™ software manufactured by Netzsch company, based on a specific heat capacity obtained from a thermal diffusivity, a density, and DSC for each sample.

Scanning ElectronMicroscope

IM4000 Plus ion milling apparatus manufactured by Hitachi High-Technologies Corporation is used to fabricate a cross section sample, and a Pt/Pd layer of 2 nm is coated on the cross section sample by a sputtering device. The cross section of the sample is then observed using S3400N manufactured by Hitachi High Technologies Corporation.

Test: Relationship of Type and Size of Filler Component, and Thermal Conductivity Rate of Thermally Conductive Sheet with respect to Compounding Ratio of Isotropic Thermally Conductive Material

### Example 1: F30/A50

Filler components t-0 and ta-4, and thermally conductive sheet precursor coating liquids TA-1 to TA-3 (sometimes simply referred to as “coating liquid”) in Table 2 were used to fabricate thermally conductive sheets, t-0 containing only an agglomerate (A50), ta-4 containing only an isotropic thermally conductive material (F30), TA-1 to TA-3 containing an agglomerate and an isotropic thermally conductive material mixed at a predetermined ratio. As an example, a method for fabricating a thermally conductive sheet prepared using TA-1 is illustrated below. A thermally conductive sheet can also be fabricated in a similar manner for other coating liquids.

NPEL-128 of 0.2 g, YDCN-700-3 of 2.57 g (MEK solution containing a solid content of 70%), and DICYANEX1400F of 0.16 g were blended in a plastic cup, and stirred using a high-speed mixer at 2000 rpm for 15 seconds. Then, the agglomerate (A50) of 5.10 g and isotropic thermally conductive material (F30) of 2.42 g as the filler components, and MEK of 4.50 g were added into to the plastic cup described above, and further stirred at 2000 rpm for 15 seconds to prepare a coating solution (TA-1) containing A50 and F30 at a ratio of 75/25.

The coating liquid (TA-1) was coated on a release PET liner (A31: available from Toray DuPont Co., Ltd.) having a thickness of 38 μm using a knife coater with gap spacing 450 μm, dried at 65° C. for 5 minutes, and thereafter, further dried at 110° C. for 5 minutes to prepare a thermally conductive sheet precursor having a thickness of about 150 μm.

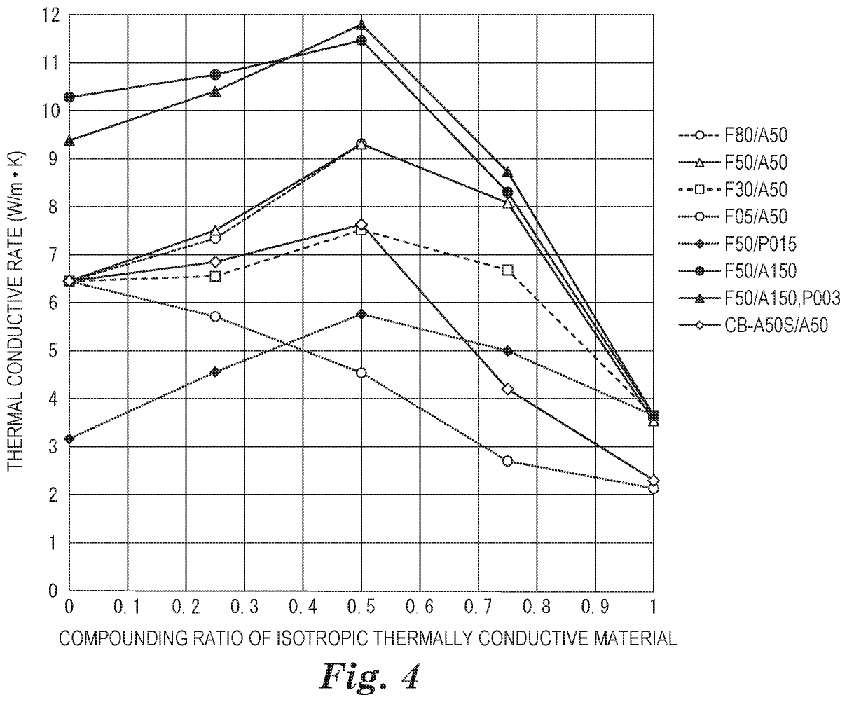

Next, two sheet precursors were laminated to obtain a laminate, and a pressure of 3 MPa was applied to the laminate at 65° C. for 5 minutes to prepare an adhesive thermally conductive sheet. Results of the compounding ratio of the isotropic thermally conductive material and the thermal conductivity rate in the resulting thermally conductive sheet are illustrated in FIG. 4. Here, embodiments in which the compounding ratio of the isotropic thermally conductive material is 0 (0%) and 1 (100%) are reference examples.

### Example 2: F50/A50

A thermally conductive sheet in Example 2 was fabricated in the same manner as in Example 1 with the exception that the coating liquids in Table 2 were used. Results of the compounding ratio of the isotropic thermally conductive material and the thermal conductivity rate in the resulting thermally conductive sheet are illustrated in FIG. 4. Here, embodiments in which the compounding ratio of the isotropic thermally conductive material is 0 (0%) and 1 (100%) are reference examples.

### Example 3: F80/A50

A thermally conductive sheet in Example 3 was fabricated in the same manner as in Example 1 with the exception that the coating liquids in Table 2 were used. Results of the compounding ratio of the isotropic thermally conductive material and the thermal conductivity rate in the resulting thermally conductive sheet are illustrated in FIG. 4. Here, an embodiment in which the compounding ratio of the isotropic thermally conductive material is 0 (0%) is a reference example.

### Example 4: F50/A150

A thermally conductive sheet in Example 4 was fabricated in the same manner as in Example 1 with the exception that the coating liquids in Table 2 were used. Results of the compounding ratio of the isotropic thermally conductive material and the thermal conductivity rate in the resulting thermally conductive sheet are illustrated in FIG. 4. Here, embodiments in which the compounding ratio of the isotropic thermally conductive material is 0 (0%) and 1 (100%) are reference examples.

### Example 5: F50/A150, P003

A thermally conductive sheet in Example 5 was fabricated in the same manner as in Example 1 with the exception that the coating liquids in Table 3 were used. Results of the compounding ratio of the isotropic thermally conductive material and the thermal conductivity rate in the resulting thermally conductive sheet are illustrated in FIG. 4. Here, embodiments in which the compounding ratio of the isotropic thermally conductive material is 0 (0%) and 1 (100%) are reference examples.

### Example 6: CB-A50S/A50

A thermally conductive sheet in Example 6 was fabricated in the same manner as in Example 1 with the exception that the coating liquids in Table 3 were used. Results of the compounding ratio of the isotropic thermally conductive material and the thermal conductivity rate in the resulting thermally conductive sheet are illustrated in FIG. 4. Here, embodiments in which the compounding ratio of the isotropic thermally conductive material is 0 (0%) and 1 (100%) are reference examples.

### Comparative Example 1: F05/A50

A thermally conductive sheet in Comparative Example 1 was fabricated in the same manner as in Example 1 with the exception that the coating liquids in Table 3 were used. Results of the compounding ratio of the isotropic thermally conductive material and the thermal conductivity rate in the resulting thermally conductive sheet are illustrated in FIG. 4.

### Comparative Example 2: F50/P015

A thermally conductive sheet in Comparative Example 2 was fabricated in the same manner as in Example 1 with the exception that the coating liquids in Table 3 were used. Results of the compounding ratio of the isotropic thermally conductive material and the thermal conductivity rate in the resulting thermally conductive sheet are illustrated in FIG. 4.

Results

Result 1

As can be seen from FIG. 4, in comparing Example 1 (F30/A50) with Comparative Example 1 (F05/A50), even if the same agglomerate (A50) was used, the thermally conductive sheet of Example 1 using the isotropic thermally conductive material (F30) having the average particle diameter of 20 μm or greater was confirmed to be able to significantly improve the thermal conductivity rate.

Result 2

In comparing Example 1 (F30/A50), Example 2 (F50/A50), and Example 3 (F80/A50), the effect of improving the thermal conductivity rate was confirmed to be improved more when the size of the isotropic thermally conductive material was greater than 30 μm.

Result 3

In comparing Example 2 (F50/A50), Example 4 (F50/A150), and Comparative Example 2 (F50/P015), even if the same isotropic thermally conductive material (F50) was used, the thermally conductive sheet containing the anisotropic thermally conductive disintegrated primary particles obtained by disintegrating the agglomerates (A50, A150) and the isotropic thermally conductive material was confirmed to be more excellent in the effect of improving the thermal conductivity rate than the thermally conductive sheet of Comparative Example 2 obtained from the mixture in which the filler (P015) and the isotropic thermally conductive material were simply blended.

FIG. 5(a) is a SEM photograph of the thermally conductive sheet in Example 4, and FIG. 5(b) is a SEM photograph of the thermally conductive sheet in Comparative Example 2. The anisotropic thermally conductive primary particles can be seen to be arranged in a random direction in the thermally conductive sheet in Example 4 as compared to the thermally conductive sheet in Comparative Example 2. Also from the results, it can be seen that a thermally conductive sheet containing anisotropic thermally conductive disintegrated primary particles obtained by disintegrating the agglomerates is more likely to exhibit isotropic thermal conductivity.

It is thought that scaly boron nitride around aluminum nitride in FIG. 5(b) has a high tendency to be stacked in the short diameter direction with low thermal conductivity rate, and therefore, a path of thermal conduction is unlikely to be formed between aluminum nitride and boron nitride. On the other hand, scaly boron nitride surrounding aluminum nitride in FIG. 5(a) is in contact with aluminum nitride at an end of a long axis with thermal conductivity rate higher as compared to the configuration of FIG. 5(b), and fine particles of finely randomly broken boron nitride are also present, and therefore, it is thought that a path of thermal conduction is likely to be formed between aluminum nitride and boron nitride.

Result 4

As can be seen from the results in Example 4 (F50/A150) and Example 5 (F50/A150, P 0 0 3) in FIG. 4, the thermally conductive sheet in Example 5 further including the filler (P003) in addition to the agglomerate (A150) was confirmed to have more improved thermal conductivity.

Result 5

As can be seen from the results in Example 6 (CB-A50S/A50) and Comparative Example 1 (F05/A50) in FIG. 4, the effect of improving the thermal conductivity was confirmed to be obtained with a specific size of the isotropic thermally conductive material regardless of the type thereof

Result 6

As for Examples 1 to 6, the effect of improving thermal conductivity rate was found to be more remarkable when the compounding ratio of the isotropic thermally conductive material is in a range from about 25 to about 75%, more preferably in a range from about 30 to about 60%.

It will be apparent to those skilled in the art that various modifications can be made to the embodiments and examples described above without departing from the basic principles of the present invention. It will also be apparent to those skilled in the art that various improvements and modifications of the present invention can be made without departing from the gist and scope of the present invention.

1. A thermally conductive sheet precursor comprising:
agglomerates in which anisotropic thermally conductive primary particles are agglomerated;
an isotropic thermally conductive material different from the agglomerates and having an average particle diameter of 20 μm or greater; and
a binder resin, wherein
when a first pressure in a range from 0.75 to 12 MPa is applied to the thermally conductive sheet precursor, at least some the agglomerates disintegrate.

2. The thermally conductive sheet precursor according to claim 1, wherein
the isotropic thermally conductive material does not disintegrate when the first pressure is applied.

3. The thermally conductive sheet precursor according to claim 1, wherein
the agglomerates have a void space ratio greater than 50%.

4. The thermally conductive sheet precursor according to claim 1, wherein
a filler component is included in the thermally conductive sheet precursor at 45 to 80 vol %, and a ratio of the agglomerates in the filler component is 20 to 95% and a ratio of the isotropic thermally conductive material in the filler component is 5 to 80%.

5. The thermally conductive sheet precursor according to claim 1, wherein
an average particle diameter of the agglomerates is 20 μm or greater.

6. The thermally conductive sheet precursor according to claim 1, wherein
the agglomerates include boron nitride primary particles.

7. The thermally conductive sheet precursor according to claim 1, wherein
the thermally conductive sheet precursor has a thickness greater than a maximum value of a short axis length of the agglomerates.

8. The thermally conductive sheet precursor according to claim 1, wherein
the isotropic thermally conductive material is at least one selected from aluminum nitride, aluminum oxide, silicon carbide, and boron nitride.

9. The thermally conductive sheet precursor according to claim 1, further comprising a filler.

10. A thermally conductive sheet formed from the thermally conductive sheet precursor according to claim 1.

11. The thermally conductive sheet according to claim 10, wherein
the thermally conductive sheet includes at least one or more potions where a plurality of primary particles disintegrated from the agglomerates locally congregate, in a circular region of 20 to 150 μm diameter in a cross section in a thickness direction.

12. A method for manufacturing a thermally conductive sheet, the method comprising:
preparing a mixture including agglomerates in which anisotropic thermally conductive primary particles are agglomerated, an isotropic thermally conductive material different from the agglomerates and having an average particle diameter of 20 μm or more, and a binder resin;
forming a thermally conductive sheet precursor by using the mixture; and
applying pressure of at least 0.75 MPa to the thermally conductive sheet precursor to form a thermally conductive sheet.
